(19) United States
(12) Patent Application Publication
(10) Pub. No.: US 2025/0056842 A1
(43) Pub. Date: Feb. 13, 2025

(54) ELECTRONIC DEVICE

(71) Applicant: InnoLux Corporation, Miao-Li County (TW)

(72) Inventor: Jhe-Ciou JHU, Miao-Li County (TW)

(73) Assignee: InnoLux Corporation, Miao-Li County (TW)

(21) Appl. No.: 18/773,549

(22) Filed: Jul. 15, 2024

(30) Foreign Application Priority Data
Aug. 11, 2023 (CN) 202311009918.8

(51) Int. Cl. H01L 29/786

(52) U.S. Cl. CPC H01L 29/7869

(57) ABSTRACT

An electronic device includes a substrate and a transistor. The transistor is disposed on the substrate and includes an oxide semiconductor, a first conductive element and a second conductive element. The oxide semiconductor is disposed on the substrate. The first conductive element is disposed between the substrate and the oxide semiconductor. The second conductive element is disposed on the oxide semiconductor and overlapped with the first conductive element. In a top view of the transistor, the second conductive element has an arc angle.

### BACKGROUND OF THE DISCLOSURE

### 1. Field of the Disclosure

The present disclosure relates to an electronic device, and more particularly, to an electronic device having an oxide semiconductor transistor.

### 2. Description of the Prior Art

The electrical property of a transistor is one of the important factors that affect the performance of the transistor. In an oxide semiconductor transistor, poor conductivity between an oxide semiconductor and an electrode would adversely affect the performance of the transistor. Therefore, how to effectively improve the conductivity between the oxide semiconductor and the electrode so as to improve the performance of the transistor and the quality of the electronic device is a technical problem that needs to be solved at present.

### SUMMARY OF THE DISCLOSURE

It is an object of the present disclosure to provide an electronic device.

An embodiment of the present disclosure provides an electronic device, which includes a substrate and a transistor. The transistor is disposed on the substrate and includes an oxide semiconductor, a first conductive element and a second conductive element. The oxide semiconductor is disposed on the substrate. The first conductive element is disposed between the substrate and the oxide semiconductor. The second conductive element is disposed on the oxide semiconductor and overlapped with the first conductive element. In a top view of the transistor, the second conductive element has an arc angle.

These and other objectives of the present disclosure will no doubt become obvious to those of ordinary skill in the art after reading the following detailed description of the embodiment that is illustrated in the various figures and drawings.

### BRIEF DESCRIPTION OF THE DRAWINGS

FIG. 1 is a cross-sectional diagram schematically illustrating an electronic device according to a first embodiment of the present disclosure.

FIG. 2 is a schematic top view of a transistor of the electronic device in the first embodiment of the present disclosure.

FIG. 3 is a partially enlarged view schematically illustrating an area Q shown in FIG. 1.

FIG. 4 is a partially enlarged view schematically illustrating an example of a conductive element serving as a gate in the first embodiment of the present disclosure.

FIG. 5 is a partially enlarged view schematically illustrating another example of the conductive element serving as the gate in the first embodiment of the present disclosure.

FIG. 6 is a cross-sectional diagram schematically illustrating a transistor according to a second embodiment of the present disclosure.

FIG. 7 is a cross-sectional diagram schematically illustrating a transistor according to a third embodiment of the present disclosure.

### DETAILED DESCRIPTION

The contents of the present disclosure will be described in detail with reference to specific embodiments and drawings. It is noted that, for purposes of illustrative clarity and being easily understood by the readers, the following drawings may be simplified schematic diagrams, and components therein may not be drawn to scale. The components and combinations thereof related to the present disclosure are shown to provide a clear description of the basic structure or implementation of the present disclosure, however, the actual components and layout may be more complicated. Additionally, the numbers, shapes and dimensions of the components in the drawings are just illustrative, and are not intended to limit the scope of the present disclosure. The detailed scales of components can be adjusted according to the designs.

Certain terms are used throughout the description and following claims to refer to particular components. As one skilled in the art will understand, electronic equipment manufacturers may refer to a component by different names. This document does not intend to distinguish between components that differ in name but not function. In the following description and claims, the terms “include” and “comprise” are used in an open-ended fashion, and thus should be interpreted to mean “include, but not limited to . . . ”.

The directional terms mentioned in this document, such as “up”, “down”, “front”, “back”, “left”, “right”, etc., are only directions referring to the drawings. Therefore, the directional terms are used for illustration, not to limit the present disclosure. In the drawings, each drawing shows the general characteristics of methods, structures and/or materials used in specific embodiments. However, these drawings should not be construed as defining or limiting the scope or nature covered by these embodiments. For example, the relative size, thickness and position of each layer, region and/or structure may be reduced or enlarged for clarity.

It should be understood that when a component or layer is referred to as being “on”, “disposed on” or “connected to” another component or layer, it may be directly on or directly connected to the other component or layer, or intervening components or layers may be presented (indirect condition). In contrast, when a component is referred to as being “directly on”, “directly disposed on” or “directly connected to” another component or layer, there are no intervening components or layers presented. In addition, the arrangement relationship between different components may be interpreted according to the contents of the drawings.

The terms “about”, “equal”, “identical” or “the same”, and “substantially” or “approximately” mentioned in this document generally mean being within 10% of a given value or range, or being within 5%, 3%, 2%, 1% or 0.5% of a given value or range.

The electrical connection or coupling can be direct electrical connection or indirect electrical connection. In the case of direct electrical connection, the end points of two components in the circuit are directly connected or connected with each other by a conductive line. In the case of indirect electrical connection, there may be switches, diodes, capacitors, inductors, resistors, other suitable components, or combinations of the above components connected between the end points of two components in the circuit, but it is not limited thereto.

It should be understood that although the terms “first”, “second”, “third”, etc. may be used herein to describe various components, these components should not be limited by these terms. These terms may be used to distinguish different components in the specification. The same terms may not be used in the claims, and the components in the claims may be described by the terms “first”, “second”, “third”, etc. according to the order of the components presented in the claims. Thus, a first component discussed below may be termed as a second component in the claims.

It should be understood that according to the following embodiments, features of different embodiments may be replaced, recombined or mixed to constitute other embodiments without departing from the spirit of the present disclosure.

The comparison of thicknesses, areas, widths, heights, or diameters between different components in the following text can be conducted by optical microscope (OM), scanning electron microscope (SEM) and other suitable instruments, and the comparison can be conducted in the same photo or more than one photo.

The electronic device of the present disclosure may include, for example, a display device, a backlight device, an antenna device, a sensing device, a wearable device, a vehicle-mounted device, or a tiled device, but it is not limited thereto. The electronic device may be a bendable, flexible or rollable electronic device. The display device may include a non-self-emissive display device or a self-emissive display device, but it is not limited thereto. The display device may include, for example, liquid crystal material, light-emitting diodes (LED), fluorescence materials, phosphorescence materials, quantum dots (QD), other suitable display medium, or combinations thereof, but it is not limited thereto. The antenna device may include, for example, a liquid crystal antenna or other kinds of antenna without liquid crystal, but it is not limited thereto. The sensing device may be used for detecting capacitance change, light, thermal energy or ultrasonic waves for example, but it is not limited thereto.

The electronic device may include electronic units, the electronic units may include passive components or active components, such as capacitors, resistors, inductors, diodes, etc. The diodes may include, for example, light emitting diodes or photodiodes, but it is not limited thereto. The light emitting diodes may include, for example, organic light emitting diodes (OLED), mini light emitting diodes (mini-LED), micro light emitting diodes (micro-LED) or quantum dots (QD) light emitting diodes, but it is not limited thereto. The tiled device may include, for example, a tiled display device or a tiled antenna device, but it is not limited thereto.

It should be noted that the electronic device of the present disclosure may be any combination of the aforementioned devices, but it is not limited thereto. In addition, the appearance of the electronic device may be rectangular, circular, polygonal, a shape with curved edges, or other suitable shapes. The electronic device may have peripheral systems such as a driving system, a control system, a light source system, a shelf system, etc., to support a display device, an antenna device, a wearable device (such as augmented reality or virtual reality device), a vehicle-mounted device (such as windshields), or a tiled device.

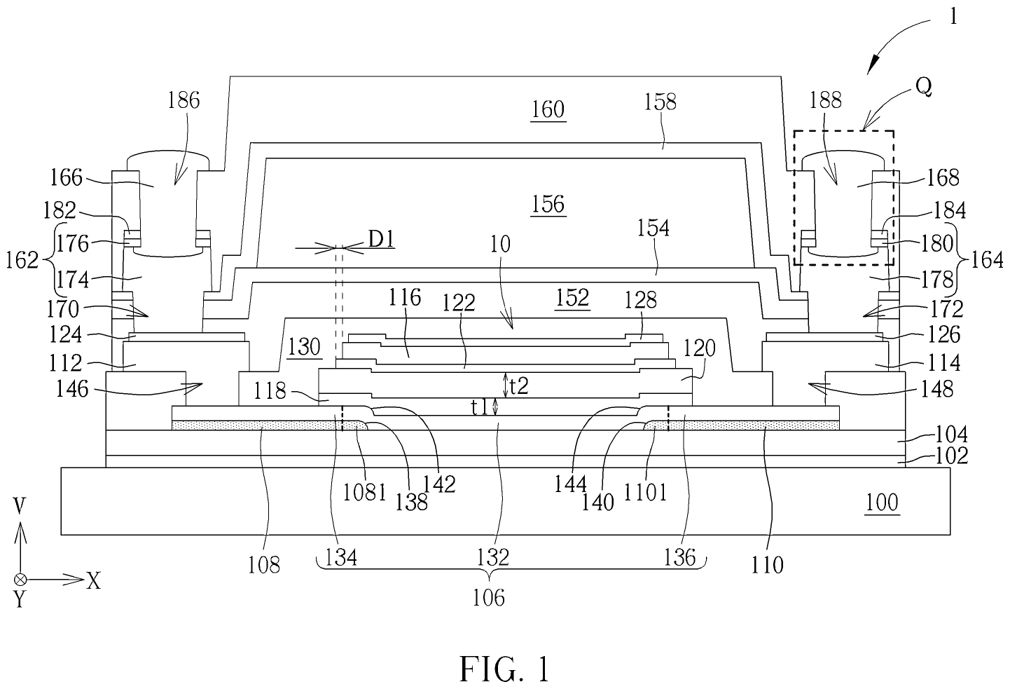

Direction V, Direction X and Direction Y are labeled in the following drawings. Direction V may be a direction normal to a plane or a top-view direction of the plane, and each of Direction X and Direction Y may be a direction parallel to the plane. As shown in FIG. 1, Direction V may be perpendicular to a surface (e.g., an upper surface or a lower surface) of a substrate 100, Direction X and Direction Y may be perpendicular to Direction V or parallel to the surface of the substrate 100, and Direction X may be perpendicular to Direction Y. The following drawings illustrate structures based on spatial relationships constituted by Direction V, Direction X and Direction Y.

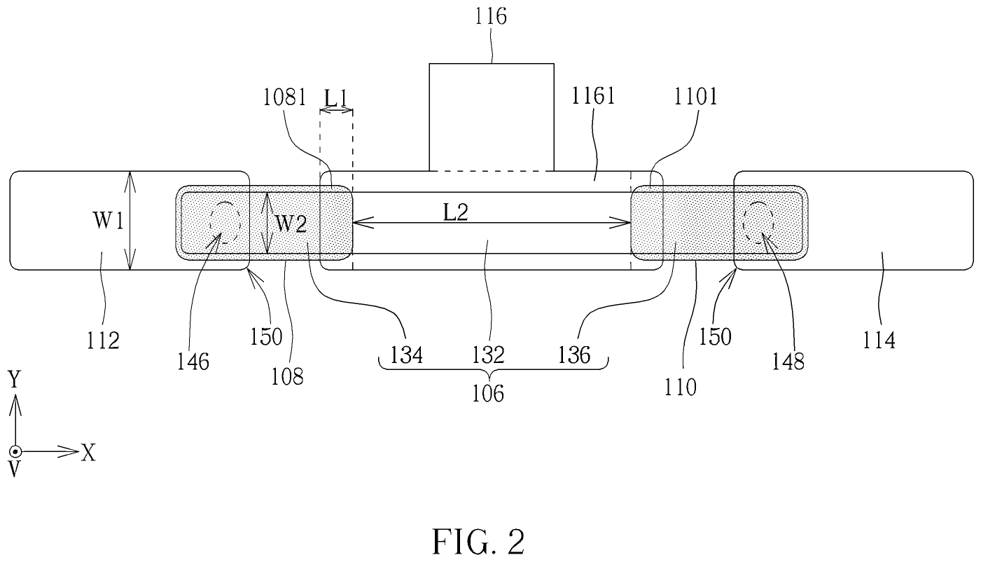

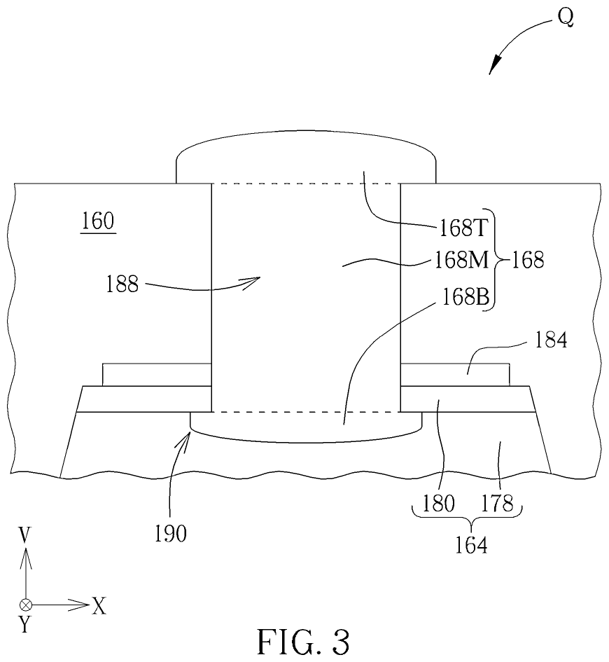

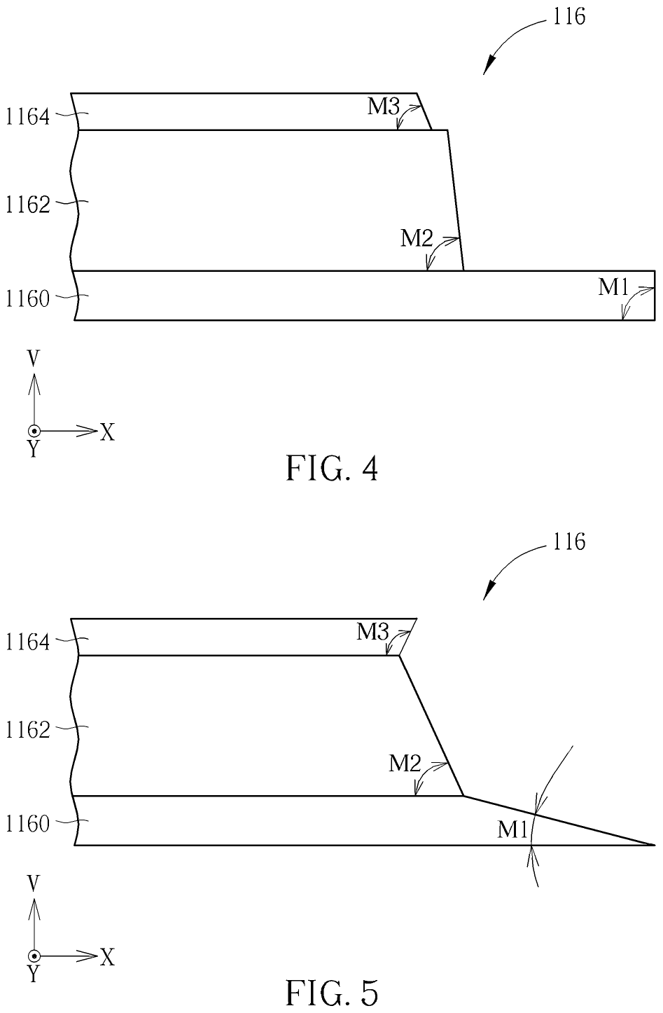

Please refer to FIGS. 1-5. FIG. 1 is a cross-sectional diagram schematically illustrating an electronic device according to a first embodiment of the present disclosure. FIG. 2 is a schematic top view of a transistor of the electronic device in the first embodiment of the present disclosure. FIG. 3 is a partially enlarged view schematically illustrating an area Q shown in FIG. 1. FIG. 4 is a partially enlarged view schematically illustrating an example of a conductive element serving as a gate in the first embodiment of the present disclosure. FIG. 5 is a partially enlarged view schematically illustrating another example of the conductive element serving as the gate in the first embodiment of the present disclosure.

As shown in FIG. 1, an electronic device 1 may include a substrate 100 and a transistor 10 disposed on the substrate 100. The material of the substrate 100 may include glass, quartz, sapphire, polymers (such as polyimide (PI) and polyethylene terephthalate (PET)), any other suitable material or a combination thereof, but it is not limited thereto. The substrate 100 may be a flexible substrate or a rigid substrate, but it is not limited thereto.

In some embodiments, the transistor 10 may be a top gate thin film transistor or a double gate thin film transistor, but it is not limited thereto. As shown in FIG. 1, the transistor 10 may include a buffer layer 102, another buffer layer 104, an oxide semiconductor 106, a conductive element 108, another conductive element 110, a further conductive element 112, yet another conductive element 114, still another conductive element 116, an insulating layer 118, another insulating layer 120, a functional layer 122, a transparent conductive layer 124, another transparent conductive layer 126, a further transparent conductive layer 128 and an interlayer dielectric layer 130, but it is not limited thereto.

The buffer layer 102 may be disposed on the substrate 100, the buffer layer 104 may be disposed on the buffer layer 102, and the buffer layer 102 may be disposed between the substrate 100 and the buffer layer 104, but it is not limited thereto. For example, the buffer layer 102 and the buffer layer 104 may include an insulating material, but it is not limited thereto. For example, the buffer layer 102 may include silicon nitride, and the buffer layer 104 may include silicon oxide, but it is not limited thereto.

The oxide semiconductor 106 may be disposed on the substrate 100. In some embodiments, the oxide semiconductor 106 may be disposed on the buffer later 104. In some embodiments, the oxide semiconductor 106 may include a first region 132, a second region 134 and another second region 136, but it is not limited thereto. The first region 132 may serve as a channel region and may be overlapped with the conductive element 116 in Direction V, and the second region 134 and the another second region 136 are disposed at opposite sides of the first region 132 in Direction X. The oxide semiconductor 106 may include a metal oxide semiconductor material, but it is not limited thereto. The metal oxide semiconductor material may include indium gallium zinc oxide (IGZO), indium gallium oxide (IGO), indium oxide (In₂O₃) and zinc oxide (ZnO), but it is not limited thereto. The thickness of the oxide semiconductor 106 may be, for example, about 300 angstroms, but it is not limited thereto.

In some embodiments, the conductive element 108 may be disposed between the substrate 100 and the second region 134 of the oxide semiconductor 106, and the conductive element 110 may be disposed between the substrate 100 and the second region 136 of the oxide semiconductor 106. In some embodiments, the conductive element 108 and the conductive element 110 may be disposed on the buffer layer 104, the conductive element 108 may be disposed between the buffer layer 104 and the second region 134 of the oxide semiconductor 106, and the conductive element 110 may be disposed between the buffer layer 104 and the second region 136 of the oxide semiconductor 106. Therefore, the second region 134 of the oxide semiconductor 106 may be overlapped with the conductive element 108, and the second region 136 of the oxide semiconductor 106 may be overlapped with the conductive element 110. In some embodiments, the conductive element 108 and the conductive element 110 may be disposed below the conductive element 116 and respectively located at opposite sides of the conductive element 116. However, it is not limited to the foregoing.

The conductive element 108 and the conductive element 110 may include a transparent conductive material, an active metal or any other suitable material, but it is not limited thereto. The transparent conductive material may include indium tin oxide (ITO), indium zinc oxide (IZO), any other suitable transparent conductive material or a combination thereof, but it is not limited thereto. For example, the conductive element 108 and the conductive element 110 may include indium tin oxide, and the thickness of the conductive element 108 and the thickness of the conductive element 110 may be about 700 angstroms, for example, but it is not limited thereto. In some embodiments, the activity of the active metal may be greater than activities of metal elements contained in the metal oxide semiconductor material, and the active metal may include, but is not limited to, titanium, aluminum or any other suitable active metal. For example, if the metal oxide semiconductor material is indium gallium zinc oxide, the activity of the active metal may be greater than that of indium, gallium and zinc, but it is not limited thereto.

The conductive element 108 may be in contact with the second region 134 of the oxide semiconductor 106, and the conductive element 110 may in contact with the second region 136 of the oxide semiconductor 106, but it is not limited thereto. As shown in FIG. 1, the conductive element 108 may be in direct contact with the second region 134 of the oxide semiconductor 106, and the conductive element 110 may be in direct contact with the second region 136 of the oxide semiconductor 106, but it is not limited thereto. By disposing the conductive element 108 and the conductive element 110, the conductivity between the second region 134 of the oxide semiconductor 106 and the conductive element 112, as well as the conductivity between the second region 136 of the oxide semiconductor 106 and the conductive element 114, can be enhanced. Accordingly, the performance of the transistor can be enhanced so as to improve the quality of the electronic device.

An edge 138 of the conductive element 108 adjacent to the conductive element 116 may have an arc angle, and an edge 140 of the conductive element 110 adjacent to the conductive element 116 may also have an arc angle. The oxide semiconductor 106 is formed on the conductive element 108 and the conductive element 110. Therefore, a surface, e.g., an upper surface, of the conductive element 106 may have an arc angle 142 on the edge 138 of the conductive element 108, and the surface of the conductive element 106 may further have an arc angle 144 on the edge 140 of the conductive element 110. Accordingly, the undulation of the oxide semiconductor 106 can be alleviated so as to reduce the probability of fracture or damage of the oxide semiconductor 106.

The insulating layer 118 may be disposed on the oxide semiconductor 106, the insulating layer 120 may be disposed on the insulating layer 118, the functional layer 122 may be disposed on the insulating layer 120, and the conductive element 116 may be disposed on the functional layer 122, but it is not limited thereto. The insulating layer 118 may be disposed between the oxide semiconductor 106 and the conductive element 116, and the insulating layer 120 may be disposed between the insulating layer 118 and the conductive element 116, but it is not limited thereto. In the present disclosure, the insulating layer may include an organic insulating material, an inorganic insulating material or a combination thereof, but it is not limited thereto. For example, the insulating layer 118 and the insulating layer 120 may include silicon oxide, but it is not limited thereto. In some embodiments, a thickness t1 of the insulating layer 118 may be less than a thickness t2 of the insulating layer 120, but it is not limited thereto.

The conductive element 116 may be overlapped with the oxide semiconductor 106, and the conductive element 116 may be overlapped with at least the first region 132 of the oxide semiconductor 106 and serve as a gate. In addition, the conductive element 116 may be partially overlapped with the conductive element 108 and the conductive element 110. In a top view (e.g., as shown in FIG. 2) of the transistor 10 in some embodiments, a portion 1081 of the conductive element 108 may be overlapped with the conductive element 116, and a portion 1101 of the conductive element 110 may be overlapped with the conductive element 116, but it is not limited thereto.

As shown in FIG. 2, a portion 1161 of the conductive element 116 is located between the conductive element 108 and the conductive element 110. A ratio of a length L1 of the portion 1081 of the conductive element 108 in Direction X to a length L2 of the portion 1161 of the conductive element 116 in Direction X may be greater than or equal to ⅓ and less than or equal to ⅔. For example, the length L1 of the portion 1081 of the conductive element 108 may be greater than or equal to 1 micron (μm) and less than or equal to 2.5 microns, and the length L2 of the portion 1161 of the conductive element 116 may be greater than or equal to 3 microns and less than or equal to 6 microns, but it is not limited thereto. The portion 1101 of the conductive element 110 may also have the same features as the portion 1081 of the conductive element 108, thus the details are not to be repeated herein.

In some embodiments, the conductive element 116 may include a single-layer structure, and the conductive element 116 may include a metal material (such as molybdenum, aluminum, copper, etc.), a transparent conductive material, any other suitable conductive material, or a combination thereof, but it is not limited thereto. In some embodiments, the conductive element 116 may include a multilayer structure, and the conductive element 116 may include molybdenum/aluminum/molybdenum, titanium-nitride/copper/copper and magnesium-aluminum alloy (Cu:MgAl), titanium-nitride/aluminum/molybdenum/indium-zinc-oxide or titanium/aluminum/molybdenum-nitride, but it is not limited thereto.

In an example as illustrated in FIG. 4, the conductive element 116 may include a multilayer structure and may include a conductive sub-element 1160, another conductive sub-element 1162 and a further conductive sub-element 1164, but it is not limited thereto. The conductive sub-element 1160 may be disposed adjacent to the oxide semiconductor 106 and may be disposed on the functional layer 122. The conductive sub-element 1162 may be disposed on the conductive sub-element 1160. The conductive sub-element 1164 may be disposed on the conductive sub-element 1162. Furthermore, the conductive sub-element 1162 may be disposed between the conductive sub-element 1160 and the conductive sub-element 1164.

The conductive sub-element 1160 may have an angle M1 at an edge of the conductive sub-element 1160. For example, the angle M1 may be an included angle between a side edge and a bottom surface of the conductive sub-element 1160. The conductive sub-element 1162 may have an angle M2 at an edge of the conductive sub-element 1162. For example, the angle M2 may be an included angle between a side edge and a bottom surface of the conductive sub-element 1162. The conductive sub-element 1164 may have an angle M3 at an edge of the conductive sub-element 1164. For example, the angle M3 may be an included angle between a side edge and a bottom surface of the conductive sub-element 1164. Furthermore, the angle M1 may be greater than the angle M2, the angle M1 may be greater than the angle M3, and the angle M2 may be greater than the angle M3, but it is not limited thereto.

For example, the conductive sub-element 1160 may include titanium, the conductive sub-element 1162 may include aluminum, and the conductive sub-element 1164 may include molybdenum nitride. The conductive sub-element 1160 may be formed by dry etching, and the conductive sub-element 1162 and the conductive sub-element 1164 may be formed by wet etching. However, it is not limited to the foregoing.

In another example as illustrated in FIG. 5, the angle M3 may be greater than the angle M2, and the angle M2 may be greater than the angle M3, but it is not limited thereto.

Referring to FIG. 1, the functional layer 122 may be disposed between the insulating layer 120 and the conductive element 116. The material of the functional layer 122 may include titanium nitride, but is not limited thereto. Through the functional layer 122, the adhesion between the insulating layer 120 and the conductive element 116 can be improved or the work function can be adjusted, but it is not limited thereto. The length of the functional layer 122 may be less than that of the insulating layer 120, thus a portion of an upper surface of the insulating layer 120 may not be covered by the functional layer 122, but it is not limited thereto.

In addition, the length of the conductive element 116 may be less than the length of the functional layer 122, thus a portion of an upper surface of the functional layer 122 may not be covered by the conductive element 116, but it is not limited to this. In Direction X and at the same side, a distance D1 between an edge of the conductive element 116 and an edge of the functional layer 122 may be 0.2 microns to 0.6 microns (0.2 μm≤distance≤0.6 μm), and the distance D1 may be, but is not limited to, about 0.3 μm, 0.4 μm or 0.5 μm.

The conductive element 112 and the conductive element 114 may be disposed on the oxide semiconductor 106 and overlapped with the conductive element 108 and the conductive element 110. In some embodiments, the interlayer dielectric layer 130 may include a contact hole 146 and a contact hole 148. The contact hole 146 may expose a portion of the upper surface of the second region 134 of the oxide semiconductor 106, and the contact hole 148 may expose a portion of the upper surface of the second region 136 of the oxide semiconductor 106. The conductive element 112 may be disposed on the interlayer dielectric layer 130 and filled in the contact hole 146. The conductive element 112 may be in direct contact with the second region 134 of the oxide semiconductor 106. Therefore, the conductive element 112 may be electrically connected to the second region 134 of the oxide semiconductor 106. The conductive element 114 may be disposed on the interlayer dielectric layer 130 and filled in the contact hole 148. The conductive element 114 may be in direct contact with the second region 136 of the oxide semiconductor 106. Therefore, the conductive element 114 may be electrically connected to the second region 136 of the oxide semiconductor 106. The conductive element 112 may be one of the source and the drain, and the conductive element 114 may be the other of the source and the drain.

In the top view (e.g., as shown in FIG. 2) of the transistor 10, each of the conductive element 112 and the conductive element 114 has an arc angle 150. The conductive element 112 has a width W1 in Direction Y, the oxide semiconductor 106 has a width W2 in Direction Y, and the width W1 is greater than the width T2. In addition, the conductive element 114 may have the same features as the conductive element 112. When the width of the conductive element 112 and the width of the conductive element 114 are greater than the width of the oxide semiconductor 106, the electric potential of the oxide semiconductor 106 can be effectively controlled through the conductive element 112 and the conductive element 114, thereby improving the electric characteristic of the transistor 10.

The conductive element 112 and the conductive element 114 may include a metal material or a transparent conductive material, but it is not limited thereto. In some embodiments, the conductive element 112 and the conductive element 114 may include a single-layer structure. The conductive element 112 and the conductive element 114 may include a metal material (such as molybdenum, aluminum, copper, etc.), a transparent conductive material, any other suitable conductive material, or a combination thereof, but it is not limited thereto. In some embodiments, the conductive element 112 and the conductive element 114 may include a multilayer structure. The conductive element 112 and the conductive element 114 may include molybdenum/aluminum/molybdenum, titanium-nitride/copper/copper and magnesium-aluminum alloy (Cu:MgAl), titanium-nitride/aluminum/molybdenum/indium-zinc-oxide or titanium/aluminum/molybdenum-nitride, but it is not limited thereto.

The transparent conductive layer 124 may be selectively disposed on the conductive element 112, the transparent conductive layer 126 may be selectively disposed on the conductive element 114, and the transparent conductive layer 128 may be selectively disposed on the conductive element 116. The length of the transparent conductive layer 124 may be less than the length of the conductive element 112. Therefore, a portion of an upper surface of the conductive element 112 may not be covered by the transparent conductive layer 124. Also, the length of the transparent conductive layer 126 may be less than the length of the conductive element 114, thus a portion of an upper surface of the conductive element 114 may not be covered by the transparent conductive layer 126. Likewise, the length of the transparent conductive layer 128 may be less than the length of the conductive element 116, thus a portion of an upper surface of the conductive element 116 may not be covered by the transparent conductive layer 128.

The transparent conductive layer in the present disclosure may include indium tin oxide, indium zinc oxide, any other suitable transparent conductive material or a combination thereof, but it is not limited thereto. In some embodiments, the conductive element 112 and the conductive element 114 may include a multilayer structure of titanium-nitride/copper, and the transparent conductive layer 124, the transparent conductive layer 126 and the transparent conductive layer 128 may include indium zinc oxide, but it is not limited thereto. The transparent conductive layer 124, the transparent conductive layer 126 and the transparent conductive layer 128 may be used for protecting the conductive element 112, the conductive element 114 and the conductive element 116 so as to reduce the probability of oxidation of the conductive element 112, the conductive element 114 and the conductive element 116.

The interlayer dielectric layer 130 may be disposed on the conductive element 116. The transparent conductive layer 128 may be disposed between the conductive element 116 and the interlayer dielectric layer 130. In addition, the interlayer dielectric layer 130 may be disposed between the second region 134 of the oxide semiconductor 106 and the conductive element 112, and may be disposed between the second region 136 of the oxide semiconductor 106 and the conductive element 114. The interlayer dielectric layer 130 may include an organic insulating material, an inorganic insulating material or a combination thereof, but it is not limited thereto. In some embodiments, the interlayer dielectric layer 130 may include silicon oxide, but it is not limited thereto.

As shown in FIG. 1, the electronic device 1 may further include an insulating layer 152, another insulating layer 154, a further insulating layer 156, yet another insulating layer 158, still another insulating layer 160, a conductive element 162, another conductive element 164, a further conductive element 166, yet another conductive element 168, a transparent conductive element 182 and another transparent conductive element 184, but it is not limited thereto. The insulating layer 152 may be disposed on the interlayer dielectric layer 130 and disposed on the conductive element 112, the conductive element 114, the transparent conductive layer 124 and the transparent conductive layer 126. The insulating layer 152 may include silicon oxynitride (SiON), but it is not limited thereto. The insulating layer 154 may be disposed on the insulating layer 152. The insulating layer 154 may include silicon oxide, but it is not limited thereto.

The insulating layer 156 may be disposed on the insulating layer 154. The insulating layer 156 may be overlapped with the conductive element 116. The insulating layer 156 may not be overlapped with at least a portion of the conductive element 112 and at least a portion of the conductive element 114. Nevertheless, it is not limited to the foregoing. The thickness of the insulating layer 156 may be 2 microns to 3 microns, and the thickness of the insulating layer 156 may be about 2.2 microns, 2.4 microns, 2.6 microns and 2.8 microns, but it is not limited thereto. The insulating layer 158 may be disposed on the insulating layer 156 and the insulating layer 154, and the insulating layer 158 may include silicon nitride, but it is not limited thereto.

The electronic device may include a contact hole 170 and another contact hole 172. The contact hole 170 may penetrate through the insulating layer 158, the insulating layer 154 and the insulating layer 152, and expose a portion of an upper surface of the transparent conductive layer 126.

The conductive element 162 may be disposed on and electrically connected to the conductive element 112, and the conductive element 164 may be disposed on and electrically connected to the conductive element 114. In some embodiments, the conductive element 162 may be disposed on the insulating layer 158 and filled in the contact hole 170, and the conductive element 162 can be in direct contact with the transparent conductive layer 124. Accordingly, the conductive element 162 can be electrically connected to the transparent conductive layer 124 and the conductive element 112. In some embodiments, the conductive element 164 may be disposed on the insulating layer 158 and filled in the contact hole 172, and the conductive element 164 can be in direct contact with the transparent conductive layer 126. Accordingly, the conductive element 164 can be electrically connected to the transparent conductive layer 126 and the conductive element 114.

The conductive element 162 and the conductive element 164 may include a metal material or a transparent conductive material, but it is not limited thereto. In some embodiments, the conductive element 162 and the conductive element 164 may include a single-layer structure. The conductive element 162 and the conductive element 164 may include a metal material (such as molybdenum, aluminum, copper, etc.), a transparent conductive material, any other suitable conductive material, or a combination thereof, but it is not limited thereto. In some embodiments, the conductive element 162 and the conductive element 164 may include a multilayer structure. The conductive element 162 and the conductive element 164 may include molybdenum/aluminum/molybdenum, titanium-nitride/copper/copper and magnesium-aluminum alloy (Cu:MgAl), titanium-nitride/aluminum/molybdenum/indium-zinc-oxide or titanium/aluminum/molybdenum-nitride, but it is not limited thereto.

As shown in FIG. 1, the conductive element 162 may include a conductive sub-element 174 and another conductive sub-element 176. The conductive sub-element 176 may be disposed on the conductive sub-element 174, but it is not limited thereto. The conductive element 164 may include a conductive sub-element 178 and another conductive sub-element 180. The conductive sub-element 180 may be disposed on the conductive sub-element 178, but it is not limited thereto. In some embodiments, the conductive sub-element 174 and the conductive sub-element 178 may include a titanium nitride layer and a copper layer disposed on the titanium nitride layer, and the conductive sub-element 176 and the conductive sub-element 180 may include an alloy layer of copper and magnalium, but it is not limited thereto.

The transparent conductive layer 182 may be selectively disposed on the conductive sub-element 176 of the conductive element 162, and the transparent conductive layer 184 may be selectively disposed on the conductive sub-element 180 of the conductive element 164. The length of the transparent conductive layer 182 may be less than the length of the conductive element 162. For example, a portion of an upper surface of the conductive sub-element 176 of the conductive element 162 may not be covered by the transparent conductive layer 182. The length of the transparent conductive layer 184 may be less than the length of the conductive element 164. For example, a portion of an upper surface of the conductive sub-element 180 of the conductive element 164 may not be covered by the transparent conductive layer 184.

In some embodiments, the transparent conductive layer 182 and the transparent conductive layer 184 may include indium zinc oxide, but it is not limited thereto. The transparent conductive layer 182 and the transparent conductive layer 184 may be used for protecting the conductive element 162 and the conductive element 164 so as to reduce the probability of oxidation of the conductive element 162 and the conductive element 164.

The insulating layer 160 may be disposed on the insulating layer 158 and may be disposed on the conductive element 162, the conductive element 164, the transparent conductive layer 182 and the transparent conductive layer 184. The thickness of the insulating layer 160 may be about 0.5 microns, but it is not limited thereto. The insulating layer 160 may include a contact hole 186 and another contact hole 188. In some embodiments, the contact hole 186 may penetrate through the transparent conductive layer 182, the conductive sub-element 176 of the conductive element 162 and a portion of the conductive sub-element 174 of the conductive element 162. The contact hole 188 may penetrate through the transparent conductive layer 184, the conductive sub-element 180 of the conductive element 164 and a portion of the conductive sub-element 178 of the conductive element 164, but it is not limited thereto.

The conductive element 166 may be disposed on and electrically connected to the conductive element 162. The conductive element 168 may be disposed on and electrically connected to the conductive element 164. As shown in FIG. 1, a portion of the conductive element 166 may be disposed on the insulating layer 160, and another portion of the conductive element 166 may be disposed in the contact hole 186 and in direct contact with the transparent conductive layer 182 and the conductive sub-element 176 and the conductive sub-element 174 of the conductive element 162, but it is not limited thereto. A portion of the conductive element 168 may be disposed on the insulating layer 160, and another portion of the conductive element 168 may be disposed in the contact hole 188 and in direct contact with the transparent conductive layer 184 and the conductive sub-element 180 and the conductive sub-element 178 of the conductive element 164, but it is not limited thereto. The conductive element 166 and the conductive element 168 may include an alloy of nickel and gold, but it is not limited thereto. In some embodiments, the electronic unit can be bonded to the conductive element 166 and/or the conductive element 168 (not shown). The transistor 10 can be electrically connected to the electronic unit through the conductive element 166 and/or the conductive element 168, but it is not limited thereto.

As shown in FIG. 3, in some embodiments, the conductive element 168 may include a top portion 168T, a middle portion 168M and a bottom portion 168B, and the middle portion 168M may be disposed between the top portion 168T and the bottom portion 168B, but it is not limited thereto. The top portion 168T may be disposed on the insulating layer 160, and the middle portion 168M and the bottom portion 168B may be disposed in the contact hole 188. The bottom 168B may be disposed under the conductive sub-element 180 of the conductive element 164. The bottom 168B may have a chamfer 190. The chamfer 190 may be disposed below an upper surface of the conductive element 164 (e.g., an upper surface of the conductive sub-element 180 of the conductive element 164 as shown in FIG. 3). In addition, the width of the top portion 168T and the width of the bottom portion 168B may be greater than the width of the middle portion 168M, but it is not limited thereto. Furthermore, the conductive element 166 may have the same features as the conductive element 168.

The content of the present disclosure is not limited to the above embodiments. Other embodiments in the present disclosure will continue to be disclosed below. However, in order to simplify the explanation and highlight the differences among the embodiments, the same elements will be denoted by the same reference numerals below, and the repetitions will not be redundantly described.

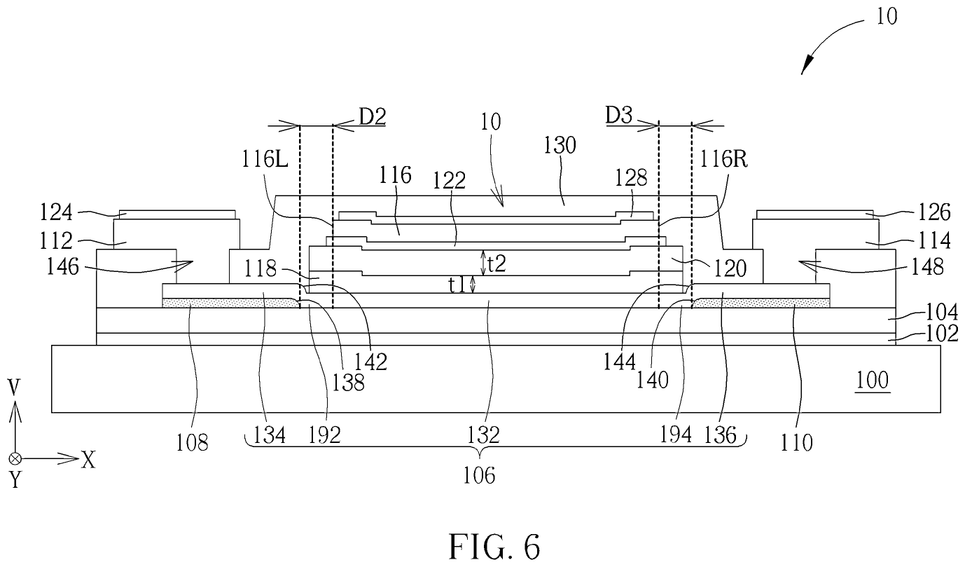

Refer to FIG. 6. FIG. 6 is a cross-sectional diagram schematically illustrating a transistor according to a second embodiment of the present disclosure. In some embodiments, the conductive element 116 may not be overlapped with the conductive element 108, and the conductive element 116 may also not be overlapped with the conductive element 110, but it is not limited thereto. An edge 116L of the conductive element 116 may be adjacent to the edge 138 of the conductive element 108, and the edge 116L of the conductive element 116 may be spaced from the edge 138 of the conductive element 108 by a distance D2 in Direction X. Another edge 116R of the conductive element 116 may be adjacent to the edge 140 of the conductive element 110, and the edge 116R of the conductive element 116 may be spaced from the edge 140 of the conductive element 110 by a distance D3 in Direction X.

In some embodiments, the oxide semiconductor 106 may include a first region 132, a second region 134, another second region 136, a third region 192 and another third region 194, but it is not limited thereto. The first region 132 may be overlapped with the conductive element 116. The second region 134 may be overlapped with the conductive element 108. The second region 136 may be overlapped with the conductive element 110. The third region 192 may be disposed between the first region 132 and the second region 134. The third region 194 may be disposed between the first region 132 and the second region 136. In Direction X, the third region 192 may be located between the extended line of the edge 116L of the conductive element 116 and the extended line of the edge 138 of the conductive element 108. The third region 194 may be located between the extended line of the edge 116R of the conductive element 116 and the extended line of the edge 140 of the conductive element 110. As the oxide semiconductor 106 includes the third region 192 and the third region 194, the high-voltage resistance of the transistor 10 can be enhanced, thereby improving the reliability of the transistor 10.

In some embodiments, the conductivity of the second region 134 and the conductivity of the second region 136 may be greater than the conductivity of the first region 132, and the conductivity of the first region 132 may be greater than the conductivity of the third regions 192 and 194. In some embodiments, the hydrogen content of the third region 192 and the third region 194 may be greater than the hydrogen content of the first region 132. In some embodiments, the hydrogen content of the third region 192 and the third region 194 may be greater than the hydrogen content of the second region 134 and the second region 136. By increasing the hydrogen content of the third region 192 and the third region 194, the conductivity of the third region 192 and the third region 194 can be consistent with that of the first region 132, or the conductivity of the third region 192 and the third region 194 can be consistent with that of the second region 134 and the second region 136.

In some embodiments, the edge 138 of the conductive element 108 may be aligned with the edge 116L of the conductive element 116, and the edge 140 of the conductive element 110 may be aligned with the edge 116R of the conductive element 116. Therefore, the oxide semiconductor 106 may not include the third region 192 and the third region 194. Furthermore, the elements shown in FIG. 1, including the insulating layer 152, the insulating layer 154, the insulating layer 156, the insulating layer 158, the insulating layer 160, the conductive element 162, the conductive element 164, the conductive element 166, the conductive element 168, the transparent conductive layer 182 and the transparent conductive layer 184, may also be joined to the structure in the second embodiment illustrated in FIG. 6 or disposed on the transistor 10 shown in FIG. 6.

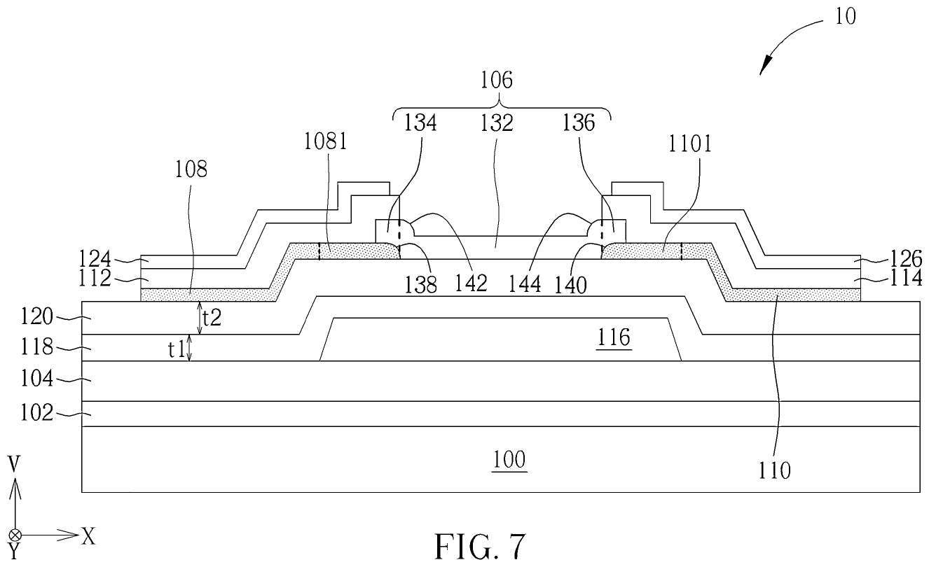

Refer to FIG. 7. FIG. 7 is a cross-sectional diagram schematically illustrating a transistor according to a third embodiment of the present disclosure. The transistor 10 in this embodiment may be a bottom gate thin film transistor, but it is not limited thereto. The conductive element 116 may be disposed on the substrate 100 and serve as the gate. The insulating layer 118 may be disposed on the substrate 100 and the conductive element 116. The insulating layer 120 may be disposed on the insulating layer 118. The conductive element 108 and the conductive element 110 may be disposed on the insulating layer 120. The conductive element 108 and the conductive element 110 may be disposed on the conductive element 116 and located at opposite sides of the conductive element 116, respectively. A portion 1081 of the conductive element 108 may be overlapped with the conductive element 116, and a portion 1101 of the conductive element 110 may be overlapped with the conductive element 116, but it is not limited thereto.

The oxide semiconductor 106 may be disposed on the insulating layer 120. The conductive element 112 may be disposed on the conductive element 108 and the oxide semiconductor 106. The conductive element 114 may be disposed on the conductive element 110 and the oxide semiconductor 106. The second region 134 of the oxide semiconductor 106 may be disposed between the portion 1081 of the conductive element 108 and the conductive element 112. The second region 136 of the oxide semiconductor 106 may be disposed between the portion 1101 of the conductive element 110 and the conductive element 114. However, it is not limited to the foregoing.

The transparent conductive layer 124 may be selectively disposed on the conductive element 112, and the transparent conductive layer 126 may be selectively disposed on the conductive element 114. The length of the transparent conductive layer 124 may be less than the length of the conductive element 112, and a portion of an upper surface of the conductive element 112 may not be covered by the transparent conductive layer 124. The length of the transparent conductive layer 126 may be less than the length of the conductive element 114, and a portion of an upper surface of the conductive element 114 may not be covered by the transparent conductive layer 126.

Furthermore, the elements shown in FIG. 1, including the insulating layer 152, the insulating layer 154, the insulating layer 156, the insulating layer 158, the insulating layer 160, the conductive element 162, the conductive element 164, the conductive element 166, the conductive element 168, the transparent conductive layer 182 and the transparent conductive layer 184, may also be joined to the structure in the third embodiment illustrated in FIG. 7 or disposed on the transistor 10 shown in FIG. 7.

To sum up, in the electronic device according to the present disclosure, the conductive element including a transparent conductive material may be disposed between the substrate and the second region of the oxide semiconductor for enhancing the conductivity between the second region of the oxide semiconductor and the conductive element serving as the source or the drain. Accordingly, the performance of the oxide semiconductor can be enhanced so as to improve the quality of the electronic device. A surface, e.g., the upper surface, of the oxide semiconductor may have an arc angle on an edge of the conductive element. Accordingly, the undulation of the oxide semiconductor can be alleviated so as to reduce the probability of fracture or damage of the oxide semiconductor. Furthermore, in a top view of the transistor, the conductive element serving as the source or the drain may have at least one arc angle.

Those skilled in the art will readily observe that numerous modifications and alterations of the device and method may be made while retaining the teachings of the disclosure. Accordingly, the above disclosure should be construed as limited only by the metes and bounds of the appended claims.

What is claimed is:

1. An electronic device, comprising:
a substrate; and
a transistor disposed on the substrate, wherein the transistor comprises:
an oxide semiconductor disposed on the substrate;
a first conductive element disposed between the substrate and the oxide semiconductor; and
a second conductive element disposed on the oxide semiconductor and overlapped with the first conductive element,
wherein, in a top view of the transistor, the second conductive element has an arc angle.

2. The electronic device according to claim 1, wherein the first conductive element is in contact with the oxide semiconductor.

3. The electronic device according to claim 1, wherein the first conductive element comprises a transparent conductive material.

4. The electronic device according to claim 1, wherein the second conductive element comprises a metal material or a transparent conductive material.

5. The electronic device according to claim 1, wherein the transistor further comprises:
a third conductive element overlapped with the oxide semiconductor; and
a fourth conductive element disposed between the substrate and the oxide semiconductor, the fourth conductive element and the first conductive element being disposed at opposite sides of the third conductive element,
wherein in the top view of the transistor, a portion of the first conductive element is overlapped with the third conductive element, a portion of the third conductive element is disposed between the first conductive element and the fourth conductive element, a ratio of a length of the portion of the first conductive element to a length of the portion of the third conductive element is greater than or equal to ⅓ and less than or equal to ⅔.

6. The electronic device according to claim 5, wherein the third conductive element comprises:
a first conductive sub-element adjacent to the oxide semiconductor, wherein in a cross-sectional view of the transistor, an edge of the first conductive sub-element has a first angle;
a second conductive sub-element disposed on the first conductive sub-element, wherein in the cross-sectional view of the transistor, an edge of the second conductive sub-element has a second angle; and
a third conductive sub-element, wherein the second conductive sub-element is disposed between the first conductive sub-element and the third conductive sub-element, and in the cross-sectional view of the transistor, an edge of the third conductive sub-element has a third angle,
wherein the first angle is greater than the second angle, and the second angle is greater than the third angle.

7. The electronic device according to claim 5, wherein the third conductive element comprises:
a first conductive sub-element adjacent to the oxide semiconductor, wherein in a cross-sectional view of the transistor, an edge of the first conductive sub-element has a first angle;
a second conductive sub-element disposed on the first conductive sub-element, wherein in the cross-sectional view of the transistor, an edge of the second conductive sub-element has a second angle; and
a third conductive sub-element, wherein the second conductive sub-element is disposed between the first conductive sub-element and the third conductive sub-element, and in the cross-sectional view of the transistor, an edge of the third conductive sub-element has a third angle,
wherein the third angle is greater than the second angle, and the second angle is greater than the first angle.

8. The electronic device according to claim 1, wherein the transistor further comprises a third conductive element overlapped with the oxide semiconductor, and an edge of the first conductive element is aligned with an edge of the third conductive element.

9. The electronic device according to claim 1, wherein the transistor further comprises a third conductive element overlapped with the oxide semiconductor, an edge of the third conductive element is adjacent to an edge of the first conductive element, and the edge of the third conductive element is spaced from the edge of the first conductive element by a distance.

10. The electronic device according to claim 9, wherein the oxide semiconductor comprises:
a first region overlapped with the third conductive element;
a second region overlapped with the first conductive element; and
a third region disposed between the first region and the second region,
wherein a conductivity of the second region is greater than a conductivity of the first region, and the conductivity of the first region is greater than a conductivity of the third region.

11. The electronic device according to claim 9, wherein the oxide semiconductor comprises:
a first region overlapped with the third conductive element;
a second region overlapped with the first conductive element; and
a third region disposed between the first region and the second region,
wherein a hydrogen content of the third region is greater than a hydrogen content of the first region.

12. The electronic device according to claim 11, wherein the hydrogen content of the third region is greater than a hydrogen content of the second region.

13. The electronic device according to claim 1, wherein the transistor further comprises:
a third conductive element overlapped with the oxide semiconductor;
a first insulating layer disposed between the oxide semiconductor and the third conductive element;
a second insulating layer disposed between the first insulating layer and the third conductive element,
wherein a thickness of the first insulating layer is less than a thickness of the second insulating layer.

14. The electronic device according to claim 1, wherein in a cross-sectional view of the transistor, a surface of the oxide semiconductor has an arc angle on an edge of the first conductive element.

15. The electronic device according to claim 1, further comprising:
a fourth conductive element disposed on the second conductive element and electrically connected to the second conductive element; and
a fifth conductive element disposed on the fourth conductive element and electrically connected to the fourth conductive element.

16. The electronic device according to claim 15, wherein the fifth conductive element has a chamfer at a bottom of the fifth conductive element, and the chamfer is disposed below an upper surface of the fourth conductive element.

17. The electronic device according to claim 15, further comprising a transparent conductive layer disposed between the second conductive element and the fourth conductive element.

18. The electronic device according to claim 17, wherein a length of a portion of the transparent conductive layer disposed on the second conductive element is less than a length of the second conductive element.

19. The electronic device according to claim 15, further comprising a transparent conductive layer disposed on the fourth conductive element, wherein the fifth conductive element is electrically connected to the fourth conductive element by passing through the transparent conductive layer.

20. The electronic device according to claim 1, wherein the transistor further comprises:
a third conductive element overlapped with the oxide semiconductor;
a fourth conductive element disposed between the substrate and the oxide semiconductor, the fourth conductive element and the first conductive element being disposed at opposite sides of the third conductive element; and
a transparent conductive layer disposed on the third conductive element.
